(19) United States
(12) Patent Application Publication
(10) Pub. No.: US 2017/0140948 A1
(43) Pub. Date: May 18, 2017

(54) SEMICONDUCTOR PACKAGE MANUFACTURING METHOD

(71) Applicant: NITTO DENKO CORPORATION, Osaka (JP)

(72) Inventors: Ryuichi Kimura, Ibaraki-shi (JP); Naohide Takamoto, Ibaraki-shi (JP); Goji Shiga, Ibaraki-shi (JP)

(21) Appl. No.: 15/349,855

(22) Filed: Nov. 11, 2016

(30) Foreign Application Priority Data
Nov. 13, 2015 (JP) 2015-222923

(51) Int. Cl. H01L 21/56

(52) U.S. Cl. CPC H01L 21/568

(57) ABSTRACT

A method is provided for manufacturing a semiconductor package capable of preventing positional dislocation of semiconductor chip(s) as a result of contraction due to thermal curing of resin(s). This relates to a semiconductor package manufacturing method comprising an operation in which semiconductor chip(s) is/are arranged over semiconductor backside protective film which is arranged over an adhesive sheet; an operation in which semiconductor backside protective film is cured; and an operation in which semiconductor chip(s) is/are sealed with resin.

### TECHNICAL FIELD

The present invention relates to a semiconductor package manufacturing method.

### BACKGROUND ART

Semiconductor backside protective films which serve to reduce warpage of semiconductor wafers and to protect semiconductor backsides are known.

### PRIOR ART REFERENCES

### Patent References

PATENT REFERENCE NO. 1: Japanese Patent Application Publication Kokai No. 2012-33636

### SUMMARY OF INVENTION

### Problem to Be Solved By the Invention

In the context of methods—wafer-level package manufacturing methods—in which a plurality of semiconductor elements are arranged on a two-sided adhesive sheet arranged on a glass plate or other such hard support body, and the plurality of semiconductor elements are sealed with sealing resin(s), it is sometimes the case that there is dislocation of semiconductor chip(s) as a result of contraction due to thermal curing of sealing resin(s). In the event that positional dislocation of semiconductor chip(s) occurs, rewiring may not be possible.

It is an object of the present invention to provide a method for manufacturing a semiconductor package capable of preventing positional dislocation of semiconductor chip(s) as a result of contraction due to thermal curing of resin(s).

### Means for Solving Problem

To solve the foregoing problems, the present invention is provided with a constitution as described below. That is, the present invention relates to a semiconductor package manufacturing method comprising an operation (A) in which semiconductor chip(s) is/are arranged over a semiconductor backside protective film which is arranged over an adhesive sheet; an operation (B) in which, following Operation (A), the semiconductor backside protective film is cured; and an operation (C) in which, following Operation (B), semiconductor chip(s) is/are sealed with resin. A method for manufacturing a semiconductor package associated with the present invention may make it possible to prevent positional dislocation of semiconductor chip(s) as a result of contraction due to thermal curing of resin(s). Where this is the case, this is so because semiconductor chip(s) are sealed with resin after adhesion between the semiconductor chip(s) and the semiconductor backside protective film has been increased as a result of curing of the semiconductor backside protective film. In accordance with a method for manufacturing a semiconductor package associated with the present invention, during dicing, semiconductor chip(s) may be protected by a post-dicing semiconductor backside protective film.

### BRIEF DESCRIPTION OF DRAWINGS

FIG. 1A is a schematic sectional diagram showing the situation that exists following a semiconductor chip placement operation in a method associated with Embodiment 1.

FIG. 1B is a schematic sectional diagram showing the situation that exists following a sealing operation in a method associated with Embodiment 1.

FIG. 2 is a schematic sectional diagram showing a laminated body.

FIG. 3 is a schematic sectional diagram showing the situation that exists following securing to a support body.

FIG. 4 is a schematic sectional diagram showing the situation that exists following semiconductor chip placement.

FIG. 5 is a schematic sectional diagram showing the situation that exists following sealing sheet placement.

FIG. 6 is a schematic sectional diagram showing the situation that exists following a press operation.

FIG. 7 is a schematic sectional diagram showing pre-dicing semiconductor package.

FIG. 8 is a schematic sectional diagram showing the situation following dicing.

FIG. 9 is a schematic sectional diagram showing the laminated body of Variation 1.

FIG. 10 is a schematic sectional diagram showing the laminated body of Variation 2.

### EMBODIMENTS FOR CARRYING OUT INVENTION

Although the present invention is described in detail below in terms of embodiments, it should be understood that the present invention is not limited only to these embodiments.

### Embodiment 1

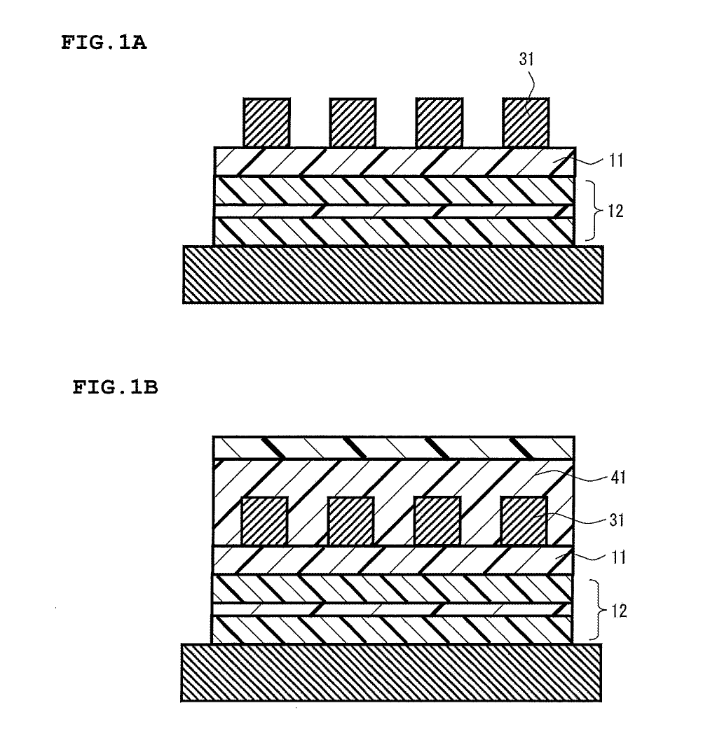

As shown in FIG. 1A, a semiconductor package manufacturing method associated with Embodiment 1 comprises an operation in which semiconductor chip(s) 31 are arranged on a semiconductor backside protective film 11 which is arranged on adhesive sheet 12; an operation in which semiconductor backside protective film 11 is cured; and, as shown in FIG. 1B, an operation in which semiconductor chip(s) 31 are sealed with resin 41. The operation in which semiconductor chip(s) 31 are sealed with resin 41 comprises a step in which resin 41 is cured. A method in accordance with Embodiment 1 may make it possible to prevent positional dislocation of semiconductor chips 31 as a result of contraction due to thermal curing of resin 41. Where this is the case, this is so because semiconductor chips 31 are sealed with resin 41 after adhesion between semiconductor chips 31 and semiconductor backside protective film 11 has been increased as a result of curing of semiconductor backside protective film 11.

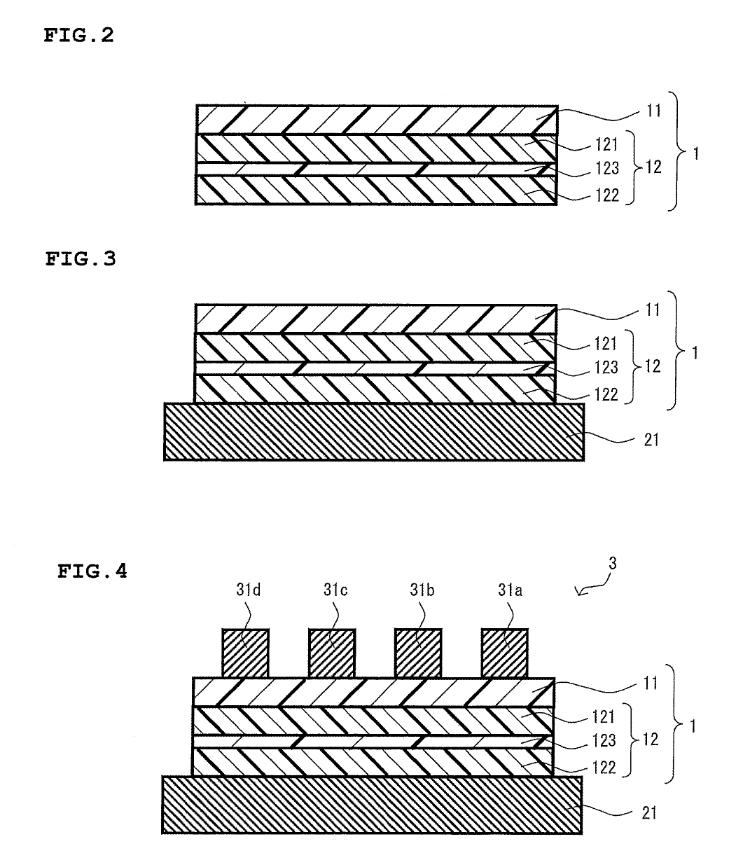

As shown in FIG. 2, laminated body 1 is first prepared. Laminated body 1 comprises adhesive sheet 12 and semiconductor backside protective film 11 which is arranged over adhesive sheet 12. Adhesive sheet 12 comprises first adhesive layer 121, second adhesive layer 122, and base layer 123 which is disposed between first adhesive layer 121 and second adhesive layer 122. The two sides of adhesive sheet 12 may be defined such that there is a first principal plane and a second principal plane opposite the first principal plane. The first principal plane of adhesive sheet 12 is the side thereof that is in contact with semiconductor backside protective film 11. First adhesive layer 121 is disposed between semiconductor backside protective film 11 and base layer 123. First adhesive layer 121 is in contact with semiconductor backside protective film 11. First adhesive layer 121 is in contact with base layer 123. First adhesive layer 121 has a property such that application of heat causes a reduction in the peel strength thereof. More specifically, this is a property such that application of heat causes foaming. Following foaming, semiconductor backside protective film 11 can be easily detached from adhesive sheet 12. In contrast, second adhesive layer 122 does not have a property such that application of heat thereto causes foaming.

As shown in FIG. 3, hard support body 21 is secured to second adhesive layer 122 of laminated body 1. Because hard support body 21 is secured to laminated body 1, stable dicing is possible. Support body 21 is planar. It is preferred that this be smooth and flat. Support body 21 might, for example, be a metal plate, a ceramic plate, a glass plate, or the like. It is preferred that support body 21 be transparent to laser light. Where this is the case, this is so as to permit semiconductor backside protective film 11 to be irradiated by a laser which is made to pass through support body 21. Thickness of support body 21 might, for example, be 0.1 mm to 50 mm.

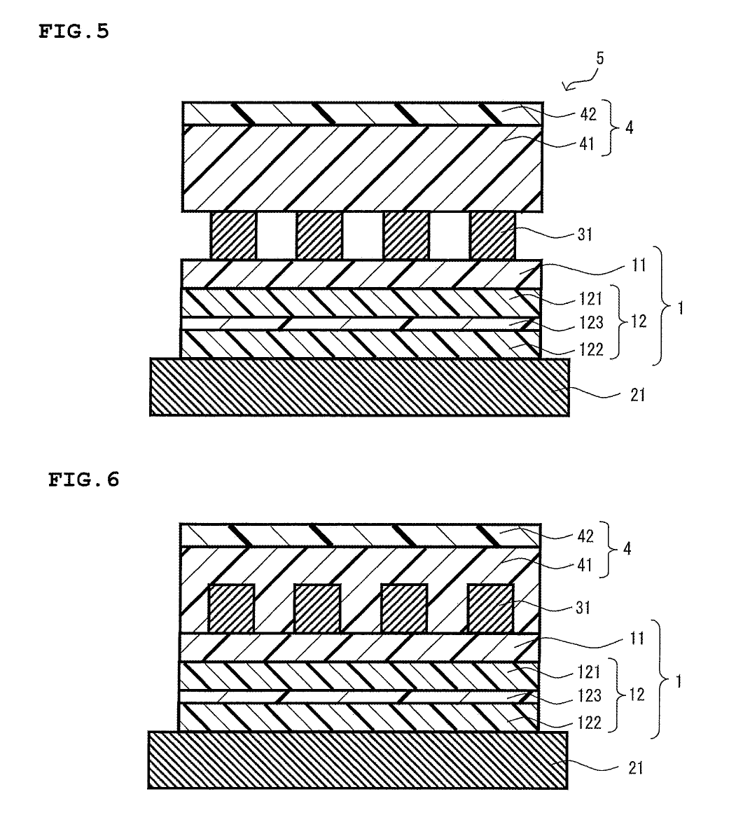

As shown in FIG. 4, semiconductor chips 31a, 31b, 31c, 31d (hereinafter sometimes referred to collectively as “semiconductor chips 31”) are arranged over semiconductor backside protective film 11 of laminated body 1. The two sides of semiconductor chip 31 may be defined such that there is a first side and a second side opposite the first side. Here, the second side of semiconductor chip 31 is in contact with semiconductor backside protective film 11. The second side of semiconductor chip 31 is sometimes referred to as the backside thereof. Assembly 3 formed as a result of the arrangement of semiconductor chips 31a, 31b, 31c, 31d over semiconductor backside protective film 11 comprises support body 21; adhesive sheet 12; semiconductor backside protective film 11; and semiconductor chips 31a, 31b, 31c, 31d.

Semiconductor backside protective film 11 is cured while in a state such that it contacts semiconductor chips 31a, 31b, 31c, 31d. More specifically, heating of assembly 3 causes curing of semiconductor backside protective film 11. Temperature might, for example, be 50° C. to 300° C. It is preferred that this be not less than 80° C., and more preferred that this be not less than 100° C. It is preferred that this be not greater than 200° C., more preferred that this be not greater than 150° C., and still more preferred that this be not greater than 140° C. Heating time might, for example, be 1 minute to 300 minutes.

As shown in FIG. 5, sealing sheet 4 comprising resin layer 41 is arranged over semiconductor chips 31a, 31b, 31c, 31d which are disposed over cured semiconductor backside protective film 11. Sealing sheet 4 comprises resin layer 41 and release liner 42 which is arranged over resin layer 41. Composite body 5 formed as a result of the arrangement of sealing sheet 4 over semiconductor chips 31a, 31b, 31c, 31d comprises support body 21; adhesive sheet 12; cured semiconductor backside protective film 11; semiconductor chips 31a, 31b, 31c, 31d; and sealing sheet 4.

As shown in FIG. 6, semiconductor chips 31a, 31b, 31c, 31d are embedded within resin layer 41. More specifically, semiconductor chips 31a, 31b, 31c, 31d are embedded within resin layer 41 by heating composite body 5 while a force is applied to composite body 5 by means of a substantially parallel pair of plates. The temperature might, for example, be 50° C. to 200° C. It is preferred that this be not less than 70° C. It is preferred that this be not greater than 120° C., and more preferred that this be not greater than 110° C.

Next, heat is applied to resin layer 41 to cause curing of resin layer 41. More specifically, the application of heat to composite body 5 after this has been subjected to the press operation causes curing of resin layer 41. The temperature might, for example, be 50° C. to 300° C. It is preferred that this be not less than 80° C., more preferred that this be not less than 120° C., and still more preferred that this be not less than 140° C. It is preferred that this be not greater than 200° C., more preferred that this be not greater than 170° C., and still more preferred that this be not greater than 160° C. The heating time might, for example, be 1 minute to 300 minutes.

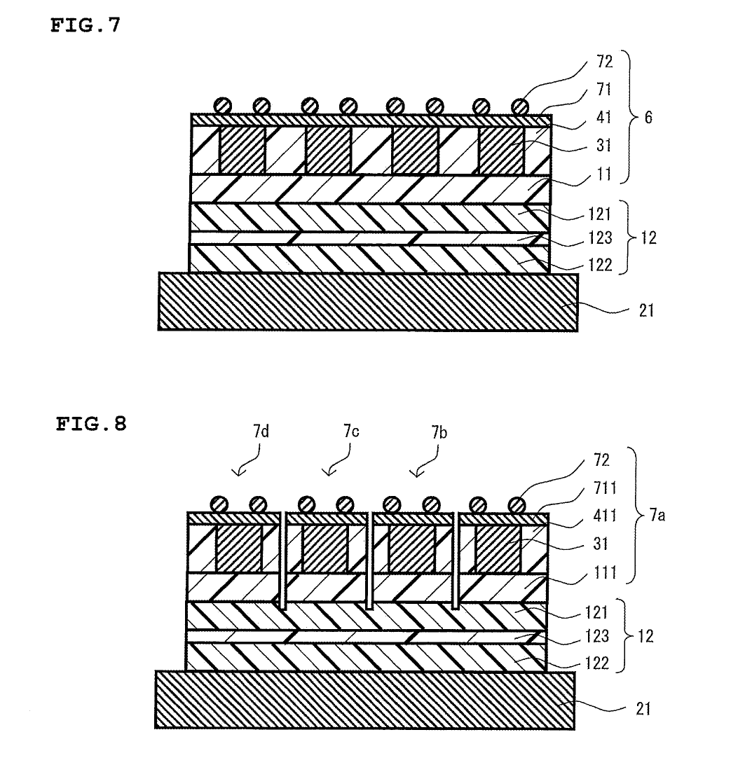

As shown in FIG. 7, pre-dicing semiconductor package 6 is formed as a result of a procedure in which release liner 42 is detached as necessary and grinding of cured resin layer 41 is carried out, layer 71 containing wiring is formed, and bumps 72 are formed. Pre-dicing semiconductor package 6 comprises cured semiconductor backside protective film 11; layer 71; semiconductor chips 31a, 31b, 31c, 31d; and post-grinding resin layer 41. Semiconductor chips 31a, 31b, 31c, 31d are disposed between layer 71 and cured semiconductor backside protective film 11. Post-grinding resin layer 41 is disposed between layer 71 and cured semiconductor backside protective film 11. That is, in the region between layer 71 and cured semiconductor backside protective film 11, that which is not in the chip region occupied by semiconductor chips 31a, 31b, 31c, 31d is occupied by post-grinding resin layer 41. Pre-dicing semiconductor package 6 further comprises bumps 72 secured to wiring. Pre-dicing semiconductor package 6 is secured to adhesive sheet 12.

As shown in FIG. 8, dicing of pre-dicing semiconductor package 6 results in formation of semiconductor packages 7a, 7b, 7c, 7d (hereinafter sometimes referred to collectively as “semiconductor packages 7”). Each semiconductor package 7 comprises post-dicing semiconductor backside protective film 111, post-dicing layer 711, semiconductor chip 31, and resin portion 411. Semiconductor chip 31 is disposed between post-dicing semiconductor backside protective film 111 and post-dicing layer 711. Resin portion 411 is disposed between post-dicing semiconductor backside protective film 111 and post-dicing layer 711. That is, in the region between post-dicing layer 711 and post-dicing semiconductor backside protective film 111, that which is not in the chip region occupied by semiconductor chip 31 is occupied by resin portion 411. Semiconductor package 7 further comprises bump(s) 72 secured to wiring. Semiconductor package 7 is secured to adhesive sheet 12.

Peel strength between semiconductor package 7 and adhesive sheet 12 is lowered. More specifically, a heater directed at support body 21 causes heat to be applied to adhesive sheet 12, as a result of which peel strength is lowered. That is, application of heat causes expansion of first adhesive layer 121. Here, it is preferred that this be heated to a temperature that is not less than 50° C. higher than the temperature for initiating expansion of thermally expansible microspheres present within first adhesive layer 121. This might, for example, be 80° C. to 250° C. It is preferred that this be not less than 100° C., more preferred that this be not less than 130° C., still more preferred that this be not less than 150° C., and even more preferred that this be not less than 160° C. It is preferred that this be not greater than 220° C., more preferred that this be not greater than 200° C., and still more preferred that this be not greater than 190° C.

A vacuum suction collet is used to detach semiconductor package 7 from adhesive sheet 12. That is, pick-up of semiconductor package 7 is carried out.

It is possible to use a laser to carry out marking of post-dicing semiconductor backside protective film 111 at semiconductor package 7. Note that known laser marking apparatuses may be employed when carrying out laser marking. Furthermore, as laser, gas lasers, solid-state lasers, liquid lasers, and the like may be employed. More specifically, as gas laser, while there is no particular limitation with respect thereto and any known gas laser may be employed, carbon dioxide gas lasers (CO₂ lasers) and excimer lasers (ArF lasers, KrF lasers, XeCl lasers, XeF lasers, etc.) are preferred. Furthermore, as solid-state laser, while there is no particular limitation with respect thereto and any known solid-state laser may be employed, YAG lasers (Nd:YAG lasers, etc.) and YVO₄ lasers are preferred.

—Laminated Body 1—

It is preferred that the peel strength (23° C.; 180° peel angle; 300 mm/min peel rate) between semiconductor backside protective film 11 and adhesive sheet 12 be 0.05 N/20 mm to 5 N/20 mm. When this is 0.05 N/20 mm or greater, cured semiconductor backside protective film 11 tends not to detach from adhesive sheet 12 during dicing.

—First Adhesive Layer 121—

First adhesive layer 121 has a property such that application of heat causes reduction in the peel strength thereof. For example, this may be a property such that application of heat causes foaming. Following foaming, semiconductor backside protective film 11 can be easily detached from adhesive sheet 12.

First adhesive layer 121 may comprise an adhesive in which the base polymer thereof is a polymer for which the dynamic modulus of elasticity in the temperature domain from normal temperature to 150° C. is 50,000 dyn/cm² to 10,000,000 dyn/cm². For example, this might be an acrylic adhesive in which the base polymer thereof is an acrylic polymer employing one, two, or more varieties of (meth)acrylic acid alkyl ester as monomer component(s).

First adhesive layer 121 comprises thermally expansible microspheres. The thermally expansible microspheres have a property such that they expand as a result of application of heat. Following expansion of the thermally expansible microspheres, semiconductor backside protective film 11 can be easily detached from adhesive sheet 12. This is due to deformation of first adhesive layer 121. The thermally expansible microspheres may comprise a substance that is transformed into a gas as a result of application of heat, and microcapsule(s) that encapsulate the substance that is transformed into a gas as a result of application of heat. The substance that is transformed into a gas as a result of application of heat might, for example, be isobutane, propane, pentane, or the like. The microcapsule(s) may comprise high-molecular-weight compound(s). For example, this might be vinylidene chloride—acrylonitrile copolymer, polyvinyl alcohol, polyvinyl butyral, polymethyl methacrylate, polyacrylonitrile, polyvinylidene chloride, polysulfone, and/or the like. Of these, high-molecular-weight thermoplastic resin(s) are preferred. Commercially available thermally expansible microspheres include microspheres sold by Matsumoto Yushi-Seiyaku Co., Ltd and the like.

It is preferred that the temperature for initiating thermal expansion of the thermally expansible microspheres be not less than 130° C. At 130° C. and higher, expansion due to heat acting on first adhesive layer 121 at or before the pick-up operation does not tend to occur. It is preferred that a bulk modulus of the thermally expansible microspheres be not less than 5, more preferred that this be not less than 7, and still more preferred that this be not less than 10. It is preferred that average particle diameter of the thermally expansible microspheres be not greater than 100 μm, more preferred that this be not greater than 80 μm, and still more preferred that this be not greater than 50 μm. The lower limit of the range in values for average particle diameter of the thermally expansible microspheres might, for example, be 1 μm. For every 100 parts by weight of the base polymer, it is preferred that the thermally expansible microspheres be present in an amount that is not less than 1 part by weight, more preferred that this be not less than 10 parts by weight, and still more preferred that this be not less than 25 parts by weight. For every 100 parts by weight of the base polymer, it is preferred that the thermally expansible microspheres be present in an amount that is not greater than 150 parts by weight, more preferred that this be not greater than 130 parts by weight, and still more preferred that this be not greater than 100 parts by weight.

It is preferred that a thickness of first adhesive layer 121 be not less than 2 μm, and more preferred that this be not less than 5 μm. It is preferred that the thickness of first adhesive layer 121 be not greater than 300 μm, more preferred that this be not greater than 200 μm, and still more preferred that this be not greater than 150 μm.

—Second Adhesive Layer 122—

Second adhesive layer 122 comprises an acrylic adhesive or other such adhesive. Second adhesive layer 122 does not have a property such that it expands as a result of application of heat. It is preferred that a thickness of second adhesive layer 122 be not less than 2 μm, and more preferred that this be not less than 5 μm. It is preferred that the thickness of second adhesive layer 122 be not greater than 300 μm, more preferred that this be not greater than 200 μm, and still more preferred that this be not greater than 150 μm.

—Base layer 123—

It is preferred that base layer 123 have a property such that a laser is transmitted therethrough (hereinafter “laser transmittance”). Semiconductor backside protective film 11 may be irradiated by a laser which is made to pass through base layer 123. It is preferred that the thickness of base layer 123 be not less than 1 μm, more preferred that this be not less than 10 μm, still more preferred that this be not less than 20 μm, and even more preferred that this be not less than 30 μm. It is preferred that the thickness of base layer 123 be not greater than 1000 μm, more preferred that this be not greater than 500 μm, still more preferred that this be not greater than 300 μm, and even more preferred that this be not greater than 200 μm.

—Semiconductor Backside Protective Film 11—

Semiconductor backside protective film 11 is colored. If this is colored, it may be possible to easily distinguish between adhesive sheet 12 and semiconductor backside protective film 11. It is preferred that semiconductor backside protective film 11 be black, blue, red, or some other deep color. It is particularly preferred that this be black. The reason for this is that this will facilitate visual recognition of laser mark(s).

The deep color means a dark color having L* that is defined in the L*a*b* color system of basically 60 or less (0 to 60), preferably 50 or less (0 to 50) and more preferably 40 or less (0 to 40).

The black color means a blackish color having L* that is defined in the L*a*b* color system of basically 35 or less (0 to 35), preferably 30 or less (0 to 30) and more preferably 25 or less (0 to 25). In the black color, each of a* and b* that is defined in the L*a*b* color system can be appropriately selected according to the value of L*. For example, both of a* and b* are preferably −10 to 10, more preferably −5 to 5, and especially preferably −3 to 3 (above all, 0 or almost 0).

L*, a*, and b* that are defined in the L*a*b* color system can be obtained by measurement using a colorimeter (tradename: CR-200 manufactured by Konica Minolta Holdings, Inc.). The L*a*b* color system is a color space that is endorsed by Commission Internationale de I'Eclairage (CIE) in 1976, and means a color space that is called a CIE1976 (L*a*b*) color system. The L*a*b* color system is provided in JIS Z 8729 in the Japanese Industrial Standards.

It is preferred that a moisture absorptivity of semiconductor backside protective film 11 when allowed to stand for 168 hours under conditions of 85° C. and 85% RH be not greater than 1 wt %, and it is more preferred that this be not greater than 0.8 wt %. By causing this to be not greater than 1 wt %, it is possible to improve laser marking characteristics. The moisture absorptivity can be controlled by means of inorganic filler content and so forth. A method for measuring the moisture absorptivity of semiconductor backside protective film 11 is as follows. That is, semiconductor backside protective film 11 is allowed to stand for 168 hours in a constant-temperature/constant-humidity chamber at 85° C. and 85% RH, following which the moisture absorptivity is determined from the percent weight loss as calculated based on measurements of weight before and after being allowed to stand.

Semiconductor backside protective film 11 is in an uncured state. The uncured state includes a semicured state. The semicured state is preferred.

It is preferred that the moisture absorptivity of the cured substance obtained when semiconductor backside protective film 11 is cured and this is allowed to stand for 168 hours under conditions of 85° C. and 85% RH be not greater than 1 wt %, and it is more preferred that this be not greater than 0.8 wt %. By causing this to be not greater than 1 wt %, it is possible to improve laser marking characteristics. The moisture absorptivity can be controlled by means of inorganic filler content and so forth. A method for measuring the moisture absorptivity of the cured substance is as follows. That is, the cured substance is allowed to stand for 168 hours in a constant-temperature/constant-humidity chamber at 85° C. and 85% RH, following which the moisture absorptivity is determined from the percent weight loss as calculated based on measurements of weight before and after being allowed to stand.

The smaller the percentage of volatile components present in semiconductor backside protective film 11 the better. More specifically, it is preferred that the percent weight loss (fractional decrease in weight) of semiconductor backside protective film 11 following heat treatment be not greater than 1 wt %, and it is more preferred that this be not greater than 0.8 wt %. Conditions for carrying out heat treatment might, for example, be 1 hour at 250° C. Causing this to be not greater than 1 wt % will result in good laser marking characteristics. There may be reduced occurrence of cracking during the reflow operation. What is referred to as percent weight loss is the value obtained when semiconductor backside protective film 11 is thermally cured and is thereafter heated at 250° C. for 1 hour.

It is preferred that the tensile storage modulus at 23 ° C. of semiconductor backside protective film 11 when in an uncured state be not less than 1 GPa, more preferred that this be not less than 2 GPa, and still more preferred that this be not less than 3 GPa. Causing this to be not less than 1 GPa will make it possible to prevent semiconductor backside protective film 11 from adhering to the carrier tape. The upper limit of the range in values for the tensile storage modulus at 23° C. thereof might, for example, be 50 GPa. The tensile storage modulus at 23° C. thereof can be controlled by means of the type(s) of resin component(s) and amount(s) in which present, the type(s) of filler(s) and amount(s) in which present, and so forth. The tensile storage modulus is measured using a “Solid Analyzer RS A2” dynamic viscoelasticity measuring device manufactured by Rheometric, Inc., in tensile mode, with sample width=10 mm, sample length=22.5 mm, sample thickness=0.2 mm, frequency=1 Hz, and temperature rise rate=10° C./min in a nitrogen atmosphere at prescribed temperature (23° C.).

While there is no particular limitation with respect to the optical transmittance for a visible light beam (wavelength=380 nm to 750 nm) (visible light transmittance) of semiconductor backside protective film 11, it is for example preferred that this be within a range such that it is not greater than 20% (0% to 20%), more preferred that this be not greater than 10% (0% to 10%), and especially preferred that this be not greater than 5% (0% to 5%). If semiconductor backside protective film 11 has a visible light transmittance that is greater than 20%, there is a possibility that this will have an adverse effect on the semiconductor chip(s) due to passage of light beam(s) therethrough. Furthermore, the visible light transmittance (%) thereof can be controlled by means of the type(s) of resin component(s) and amount(s) in which present, the type(s) of colorant(s) (pigment(s), dye(s), and/or the like) and amount(s) in which present, the amount(s) in which inorganic filler(s) are present, and so forth at semiconductor backside protective film 11.

A visible light transmittance (%) of semiconductor backside protective film 11 may be measured as follows. That is, semiconductor backside protective film 11, of thickness (average thickness) 20 μm, is fabricated by itself. Next, the semiconductor backside protective film 11 is irradiated with a visible light beam of wavelength=380 nm to 750 nm (device=visible light generator manufactured by Shimadzu Corporation; product name “ABSORPTION SPECTRO PHOTOMETER”) and prescribed intensity, and intensity of the visible light beam that is transmitted therethrough is measured. Moreover, the value for the visible light transmittance may be determined from the change in intensity as calculated based on measurements of a visible light beam before and after being transmitted through semiconductor backside protective film 11.

It is preferred that semiconductor backside protective film 11 comprise a colorant. The colorant might, for example, be dye(s) and/or pigment(s). Of these, dye(s) are preferred, and black dye(s) are more preferred.

It is preferred that colorant(s) be present in semiconductor backside protective film 11 in an amount that is not less than 0.5 wt %, more preferred that this be not less than 1 wt %, and still more preferred that this be not less than 2 wt %. It is preferred that colorant(s) be present in semiconductor backside protective film 11 in an amount that is not greater than 10 wt %, more preferred that this be not greater than 8 wt %, and still more preferred that this be not greater than 5 wt %.

Semiconductor backside protective film 11 may comprise thermoplastic resin. As the thermoplastic resin, natural rubber; butyl rubber; isoprene rubber; chloroprene rubber; ethylene—vinyl acetate copolymer; ethylene—acrylic acid copolymer; ethylene—acrylic acid ester copolymer; polybutadiene resin; polycarbonate resin; thermoplastic polyimide resin; nylon 6, nylon 6,6, and other such polyamide resins; phenoxy resin; acrylic resin; PET (polyethylene terephthalate), PBT (polybutylene terephthalate), and other such saturated polyester resins; polyamide-imide resin; fluorocarbon resin; and the like may be cited as examples. Any one of these thermoplastic resins may be used alone, or two or more species chosen from thereamong may be used in combination. Of these, acrylic resin and phenoxy resin are preferred.

It is preferred that thermoplastic resin be present in semiconductor backside protective film 11 in an amount that is not less than 10 wt %, and it is more preferred that this be not less than 30 wt %. It is preferred that thermoplastic resin be present in semiconductor backside protective film 11 in an amount that is not greater than 90 wt %, and it is more preferred that this be not greater than 70 wt %.

Semiconductor backside protective film 11 comprises thermosetting resin. As the thermosetting resin, epoxy resin, phenolic resin, amino resin, unsaturated polyester resin, polyurethane resin, silicone resin, thermosetting polyimide resin, and so forth may be cited as examples. Any one of these thermosetting resins may be used alone, or two or more species chosen from thereamong may be used in combination. As the thermosetting resin, epoxy resin having low content of ionic impurities and/or other substances causing corrosion of semiconductor chips is particularly preferred. Furthermore, as a curing agent for epoxy resin, phenolic resin may be preferably employed.

The epoxy resin is not especially limited, and examples thereof include bifunctional epoxy resins and polyfunctional epoxy resins such as a bisphenol A type epoxy resin, a bisphenol F type epoxy resin, a bisphenol S type epoxy resin, a brominated bisphenol A type epoxy resin, a hydrogenated bisphenol A type epoxy resin, a bisphenol AF type epoxy resin, a bisphenyl type epoxy resin, a naphthalene type epoxy resin, a fluorene type epoxy resin, a phenol novolak type epoxy resin, an ortho-cresol novolak type epoxy resin, a trishydroxyphenylmethane type epoxy resin, and a tetraphenylolethane type epoxy resin, a hydantoin type epoxy resin, a trisglycidylisocyanurate type epoxy resin, and a glycidylamine type epoxy resin.

The phenolic resin acts as a curing agent for the epoxy resin, and examples thereof include novolak type phenolic resins such as a phenol novolak resin, a phenol aralkyl resin, a cresol novolak resin, a tert-butylphenol novolak resin, and a nonylphenol novolak resin, a resol type phenolic resin, and polyoxystyrenes such as polyparaoxystyrene. The phenolic resins can be used alone or two types or more can be used together. Among these phenolic resins, a phenol novolak resin and a phenol aralkyl resin are especially preferable because connection reliability in a semiconductor device can be improved.

The phenolic resin is suitably compounded in the epoxy resin so that a hydroxyl group in the phenolic resin to 1 equivalent of an epoxy group in the epoxy resin component becomes 0.5 to 2.0 equivalents. The ratio is more preferably 0.8 to 1.2 equivalents.

It is preferred that thermosetting resin be present in semiconductor backside protective film 11 in an amount that is not less than 2 wt %, and it is more preferred that this be not less than 5 wt %. It is preferred that thermosetting resin be present in semiconductor backside protective film 11 in an amount that is not greater than 40 wt %, and it is more preferred that this be not greater than 20 wt %.

Semiconductor backside protective film 11 may comprise a curing accelerator catalyst. For example, this might be an amine-type curing accelerator, a phosphorous-type curing accelerator, an imidazole-type curing accelerator, a boron-type curing accelerator, a phosphorous-/boron-type curing accelerator, and/or the like.

To cause semiconductor backside protective film 11 to undergo crosslinking to a certain extent in advance, it is preferred that polyfunctional compound(s) that react with functional group(s) and/or the like at end(s) of polymer molecule chain(s) be added as crosslinking agent at the time of fabrication thereof. This will make it possible to improve adhesion characteristics at high temperatures and to achieve improvements in heat-resistance.

Semiconductor backside protective film 11 may comprise filler. Inorganic filler is preferred. This inorganic filler might, for example, be silica, clay, gypsum, calcium carbonate, barium sulfate, alumina, beryllium oxide, silicon carbide, silicon nitride, aluminum, copper, silver, gold, nickel, chromium, lead, tin, zinc, palladium, solder, and/or the like. Any one of these fillers may be used alone, or two or more species chosen from thereamong may be used in combination. Of these, silica is preferred, and fused silica is particularly preferred. It is preferred that an average particle diameter of the inorganic filler be within the range 0.1 μm to 80 μm. The average particle diameter of the inorganic filler might, for example, be measured using a laser-diffraction-type particle size distribution measuring device.

It is preferred that the filler be present in semiconductor backside protective film 11 in an amount that is not less than 10 wt %, and it is more preferred that this be not less than 20 wt %. It is preferred that filler be present in semiconductor backside protective film 11 in an amount that is not greater than 70 wt %, and it is more preferred that this be not greater than 50 wt %.

Semiconductor backside protective film 11 may comprise other additive(s) as appropriate. As other additive(s), flame retardant, silane coupling agent, ion trapping agent, expander, antioxidizer, antioxidant, surface active agent, and so forth may be cited as examples.

It is preferred that a thickness of semiconductor backside protective film 11 be not less than 2 μm, more preferred that this be not less than 4 μm, still more preferred that this be not less than 6 μm, and particularly preferred that this be not less than 10 μm. It is preferred that the thickness of semiconductor backside protective film 11 be not greater than 200 μm, more preferred that this be not greater than 160 μm, still more preferred that this be not greater than 100 μm, and particularly preferred that this be not greater than 80 μm.

—Sealing Sheet 4—

Sealing sheet 4 comprises resin layer 41 and release liner 42 which is arranged over resin layer 41. It is preferred that a thickness of resin layer 41 be not less than 10 μm, more preferred that this be not less than 20 μm, and still more preferred that this be not less than 30 μm. It is preferred that the thickness of resin layer 41 be not greater than 1000 μm, more preferred that this be not greater than 300 μm, and still more preferred that this be not greater than 200 μm.

Resin layer 41 comprises thermosetting resin. As the thermosetting resin, epoxy resin, phenolic resin, and so forth may be cited as examples.

The epoxy resin is not particularly limited, and examples thereof include triphenylmethane type epoxy resin, cresol novolak type epoxy resin, biphenyl type epoxy resin, modified bisphenol A type epoxy resin, bisphenol A type epoxy resin, bisphenol F type epoxy resin, modified bisphenol F type epoxy resin, dicyclopentadiene type epoxy resin, phenol novolak type epoxy resin, phenoxy resin, and other various epoxy resins. These epoxy resins may be used alone or in combination of two or more thereof.

In order to secure reactivity, the epoxy resin is preferably a resin which has an epoxy equivalent of 150 to 250, and has a softening point or melting point of 50 to 130° C. to be solid at room temperature. Out of the species of the epoxy resin, more preferred are the triphenylmethane type epoxy resin, the cresol novolak type epoxy resin, and the biphenyl type epoxy resin from the viewpoint of the reliability of the resin sheet. Preferred is the bisphenol F type epoxy resin.

The phenolic resin is not particularly limited as long as it initiates a curing reaction with an epoxy resin. Examples thereof include a phenol novolak resin, a phenolaralkyl resin, a biphenylaralkyl resin, a dicyclopentadiene-type phenolic resin, a cresol novolak resin, and a resol resin. These phenolic resins may be used either alone or in combination of two or more thereof.

A phenolic resin having a hydroxyl equivalent of 70 to 250 and a softening point of 50° C. to 110° C. is preferably used from the viewpoint of reactivity with the epoxy resin. Among these phenolic resins, a phenol novolak resin can be preferably used from the viewpoint of its high curing reactivity. Further, a phenolic resin having low moisture absorption such as a phenolaralkyl resin and a biphenylaralkyl resin can also be suitably used from the viewpoint of its reliability.

It is preferred that epoxy resin and phenolic resin be present within resin layer 41 in a combined amount that is not less than 5 wt %. When this is not less than 5 wt %, this may make it possible to obtain satisfactory force of adhesion with respect to semiconductor chip(s) and/or the like. It is preferred that epoxy resin and phenolic resin be present within resin layer 41 in a combined amount that is not greater than 40 wt %, and more preferred that this be not greater than 20 wt %. When this not greater than 40 wt %, it may be possible to reduce moisture ab sorption characteristics.

From the standpoint of curing reaction characteristics, it is preferred that a blending ratio of epoxy resin and phenolic resin be such that there are 0.7 to 1.5, and more preferred that there are 0.9 to 1.2, total hydroxyl group equivalents attributable to phenolic resin blended therewithin per epoxy group equivalent attributable to epoxy resin.

It is preferred that resin layer 41 comprise curing accelerator. As the curing accelerator, while there is no particular limitation so long as it promotes curing of the epoxy resin and the phenolic resin, 2-methylimidazole (product name: 2MZ), 2-undecylimidazole (product name: C11-Z), 2-heptadecylimidazole (product name: C17Z), 1,2-dimethylimidazole (product name: 1.2DMZ), 2-ethyl-4-methylimidazole (product name: 2E4MZ), 2-phenylimidazole (product name: 2PZ), 2-phenyl-4-methylimidazole (product name: 2P4MZ), 1-benzyl-2-methylimidazole (product name: 1B2MZ), 1-benzyl-2-phenylimidazole (product name: 1B2PZ), 1-cyanoethyl-2-methylimidazole (product name: 2MZ-CN), 1-cyanoethyl-2-undecylimidazole (product name: C11Z-CN), 1-cyanoethyl-2-phenylimidazolium-trimellitate (product name: 2PZCNS-PW), 2,4-diamino-6-[2′-methylimidazolyl-(1′)]-ethyl-s-triazine (product name: 2MZ-A), 2,4-diamino-6-[2′-undecylimidazolyl-(1′)]-ethyl-s-triazine (product name: C11Z-A), 2,4-diamino-6-[2′-ethyl-4′-methylimidazolyl-(1′)]-ethyl-s-triazine (product name: 2E4MZ-A), 2,4-diamino-6-[2′-methylimidazolyl-(1′)]-ethyl-s-triazineisocyanuric acid adduct (product name: 2MA-OK), 2-phenyl-4,5-dihydroxymethylimidazole (product name: 2PHZ-PW), 2-phenyl-4-methyl-5-hydroxymethylimidazole (product name: 2P4MHZ-PW), and/or other such imidazole-type curing accelerators may be cited as examples (all manufactured by Shikoku Chemicals Corporation). Of these, imidazole-type curing accelerators being preferred for the reason that they permit control of the curing reaction at kneading temperature during fabrication of resin layer 41, 2-phenyl-4,5-dihydroxymethylimidazole and 2,4-diamino-6-[2′-ethyl-4′-methylimidazolyl-(1′)]-ethyl-s-triazine are more preferred, and 2-phenyl-4,5-dihydroxymethylimidazole is still more preferred.

For every 100 parts by weight of the combined total of epoxy resin and phenolic resin, it is preferred that the curing accelerator be present in an amount that is not less than 0.2 part by weight, more preferred that this be not less than 0.5 part by weight, and still more preferred that this be not less than 0.8 part by weight. For every 100 parts by weight of the combined total of epoxy resin and phenolic resin, it is preferred that the curing accelerator be present in an amount that is not greater than 5 parts by weight, and more preferred that this be not greater than 2 parts by weight.

Resin layer 41 may comprise thermoplastic resin. As the thermoplastic resin, elastomers are preferred. As the thermoplastic resin, natural rubber; butyl rubber; isoprene rubber; chloroprene rubber; ethylene—vinyl acetate copolymer; ethylene—acrylic acid copolymer; ethylene—acrylic acid ester copolymer; polybutadiene resin; polycarbonate resin; thermoplastic polyimide resin; nylon 6, nylon 6,6, and other such polyamide resins; phenoxy resin; acrylic resin; PET, PBT, and other such saturated polyester resins; polyamide-imide resin; fluorocarbon resin; styrene—isobutylene—styrene triblock copolymer; methyl methacrylate—butadiene—styrene copolymer (MBS resin); and the like may be cited. Any one of these thermoplastic resins may be used alone or two or more species chosen from thereamong may be used in combination.

It is preferred that thermoplastic resin be present within resin layer 41 in an amount that is not less than 1 wt %. When this is not less than 1 wt %, this will make it possible to impart flexibility and plasticity thereto. It is preferred that the thermoplastic resin be present within resin layer 41 in an amount that is not greater than 30 wt %, more preferred that this be not greater than 10 wt %, and still more preferred that this be not greater than 5 wt %. When this is not greater than 30 wt %, this may make it possible to obtain satisfactory force of adhesion with respect to semiconductor chip(s) and/or the like.

Resin layer 41 may comprise filler. It is preferred that average particle diameter of the filler be not less than 0.5 more preferred that this be not less than 1 μm, and still more preferred that this be not less than 3 μm. It is preferred that average particle diameter of the filler be not greater than 50 μm, more preferred that this be not greater than 30 μm, and still more preferred that this be not greater than 20 μm. As the filler, inorganic filler may be cited as an example. As the inorganic filler, quartz glass, talc, silica (fused silica, crystalline silica, and/or the like), alumina, aluminum nitride, silicon nitride, boron nitride, and/or the like may be cited as examples. Of these, for the reason that they may satisfactorily permit reduction in coefficient of thermal expansion, silica and alumina are preferred, and silica is more preferred. As silica, for the reason that it has excellent flow characteristics, fused silica is preferred, and spherical fused silica is more preferred. The inorganic filler which may be employed may have been treated (pretreated) with a silane coupling agent. This will permit improvement in inorganic filler dispersion characteristics.

It is preferred that filler be present within resin layer 41 in an amount that is not less than 20 vol %, more preferred that this be not less than 70 vol %, and still more preferred that this be not less than 74 vol %. It is preferred that filler be present in an amount that is not greater than 90 vol %, and more preferred that this be not greater than 85 vol %.

Filler content may also be described in terms of units measured in “wt %”. Silica content is typically described in terms of units measured in “wt %”. Because silica ordinarily has a specific gravity of 2.2 g/cm³, preferred ranges of silica content (in wt %) might, for example, be as follows. That is, it is preferred that silica be present within resin layer 41 in an amount that is not less than 81 wt %, and more preferred that this be not less than 84 wt %. It is preferred that silica be present within resin layer 41 in an amount that is not greater than 94 wt %, and more preferred that this be not greater than 91 wt %.

Because alumina ordinarily has a specific gravity of 3.9 g/cm³, preferred ranges of alumina content (in wt %) might, for example, be as follows. That is, it is preferred that alumina be present within resin layer 41 in an amount that is not less than 88 wt %, and more preferred that this be not less than 90 wt %. It is preferred that alumina be present within resin layer 41 in an amount that is not greater than 97 wt %, and more preferred that this be not greater than 95 wt %.

Besides the foregoing constituents, flame retardant constituent(s), pigment(s), and/or the like might be present as appropriate within resin layer 41. As flame retardant constituent(s), aluminum hydroxide, magnesium hydroxide, ferrous hydroxide, calcium hydroxide, tin hydroxide, conjugated metal hydroxide, and/or any other among such various metal hydroxides, phosphazene compounds, and/or the like might, for example, be employed. Of these, for the reason that they have excellent cured strength and flame retardant properties, phosphazene compounds are preferred. As the pigment, while there is no particular limitation with respect thereto, carbon black and the like may be cited as examples.

Release liner 42 might, for example, be polyethylene terephthalate (PET) film.

—Variation 1—

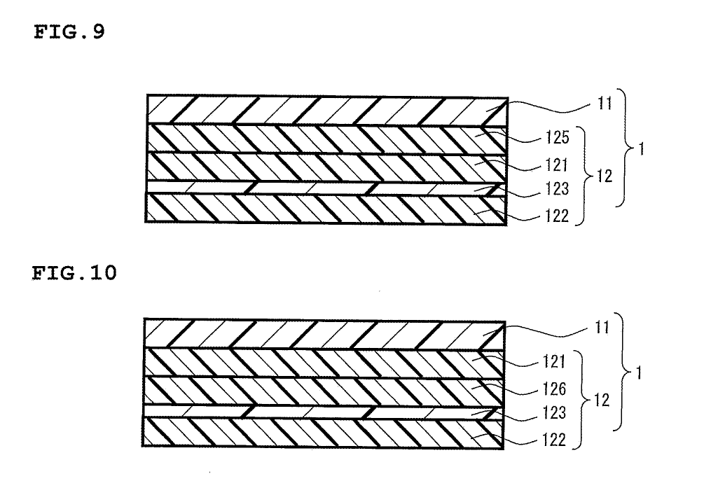

As shown in FIG. 9, in accordance with Variation 1, adhesive sheet 12 further comprises non-thermally-expansible third adhesive layer 125. Third adhesive layer 125 is disposed between first adhesive layer 121 and semiconductor backside protective film 11. Third adhesive layer 125 does not have a property such that it expands as a result of application of heat. Contaminants—gas, organic components, and so forth—generated at the time of expansion of thermally expansible microspheres are prevented from migrating from first adhesive layer 121 to semiconductor backside protective film 11 by third adhesive layer 125.

—Variation 2—

As shown in FIG. 10, in accordance with Variation 2, adhesive sheet 12 further comprises rubber-like organic elastic layer 126 which is disposed between first adhesive layer 121 and base layer 123. Rubber-like organic elastic layer 126 may prevent deformation produced by first adhesive layer 121 as a result of expansion from propagating to second adhesive layer 122 and/or the like. Rubber-like organic elastic layer 126 does not have a property such that it expands as a result of application of heat. Principal constituent(s) of rubber-like organic elastic layer 126 is/are synthetic rubber, synthetic resin, and/or the like. It is preferred that a thickness of rubber-like organic elastic layer 126 be not less than 3 μm, and more preferred that this be not less than 5 μm. It is preferred that the thickness of rubber-like organic elastic layer 126 be not greater than 500 μm, more preferred that this be not greater than 300 μm, and still more preferred that this be not greater than 150 μm.

—Variation 3—

In accordance with Variation 3, semiconductor backside protective film 11 is cured, and semiconductor chips 31a, 31b, 31c, 31d disposed over cured semiconductor backside protective film 11 are sealed by means of transfer molding or compression molding.

—Variation 4—

In accordance with Variation 4, semiconductor backside protective film 11 is cured, laser marking of cured semiconductor backside protective film 11 is carried out by a laser which is made to pass through support body 21, and sealing sheet 4 is arranged over semiconductor chips 31a, 31b, 31c, 31d.

—Variation 5—

In accordance with Variation 5, pre-dicing semiconductor package 6 is formed, laser marking of cured semiconductor backside protective film 11 is carried out by a laser which is made to pass through support body 21, and pre-dicing semiconductor package 6 is subjected to dicing.

—Variation 6—

In accordance with Variation 6, dicing is carried out to form semiconductor packages 7, laser marking of post-dicing semiconductor backside protective film 111 is carried out by a laser which is made to pass through support body 21, and adhesive sheet 12 is heated.

—Variation 7—

In accordance with Variation 7, adhesive sheet 12 is heated, laser marking of post-dicing semiconductor backside protective film 111 is carried out by a laser which is made to pass through support body 21, and semiconductor package(s) are detached from first adhesive layer 121.

—Miscellaneous—

Any of Variation 1 through Variation 7 and/or the like may be combined as desired.

As described above, a semiconductor package manufacturing method associated with Embodiment 1 comprises an operation in which hard support body 21 is secured to the second principal plane of adhesive sheet 12; an operation in which semiconductor chip(s) 31 are arranged on semiconductor backside protective film 11 which is arranged on the first principal plane of adhesive sheet 12; an operation in which semiconductor backside protective film 11 is cured; and an operation in which semiconductor chip(s) 31 are sealed with resin 41.

### WORKING EXAMPLES

Below, an exemplary detailed description of this invention is given in terms of preferred working examples. Note, however, that except where otherwise described as limiting, the materials, blended amounts, and so forth described in these working examples are not intended to limit the scope of the present invention thereto.

### Working Example 1

### —Fabrication of Semiconductor Backside Protective Film—

For every 100 parts by weight of the solids content—i.e., the solids content exclusive of solvent—of acrylic-acid-ester-type polymer (Paracron W-197C; manufactured by Negami Chemical Industrial Co., Ltd) having ethyl acrylate and methyl methacrylate as principal constituents, 10 parts by weight of epoxy resin (HP-4700; manufactured by Dainippon Ink And Chemicals, Incorporated), 10 parts by weight of phenolic resin (MEH7851-H; manufactured by Meiwa Plastic Industries, Ltd.), 85 parts by weight of spherical silica (SO-25R; spherical silica having average particle diameter 0.5 μm; manufactured by Admatechs Company Limited), 10 parts by weight of dye (OIL BLACK BS; manufactured by Orient Chemical Industries Co., Ltd.), and 10 parts by weight of catalyst (2PHZ; manufactured by Shikoku Chemicals Corporation) were dissolved in methyl ethyl ketone to prepare a resin composition solution having a solids concentration of 23.6 wt %. The resin composition solution was applied to a release liner (polyethylene terephthalate film of thickness 50 μm which had been subjected to silicone mold release treatment), and this was dried for 2 minutes at 130° C. In accordance with the foregoing means, a film of average thickness 20 μm was obtained. A disk-shaped piece of film (hereinafter referred to in the Working Examples as “Semiconductor Backside Protective Film”) of diameter 230 mm was cut out of the film.

—Fabrication of Laminated Body—

A hand roller was used to apply the semiconductor backside protective film to the thermal release adhesive layer of a two-sided adhesive sheet (Revalpha 3195V; manufactured by Nitto Denko Corporation) to fabricate a laminated body. The laminated body comprised the two-sided adhesive sheet and the semiconductor backside protective film secured to the thermal release adhesive layer (see FIG. 2).

—Sealing—

A glass plate was secured to the two-sided adhesive sheet of the laminated body (see FIG. 3). A chip that was 5 mm square (thickness 0.1 mm) was compression-bonded at 120° C. to the semiconductor backside protective film of the laminated body (see FIG. 4). The assembly comprising the glass plate, the two-sided adhesive sheet, the semiconductor backside protective film, and the chip that was 5 mm square was heated at 120° C. for 120 minutes to cure the semiconductor backside protective film. The chip that was 5 mm square was embedded in a sheet-like sealing resin, and the sealing resin was cured by heating at 150° C. for 120 minutes (see FIGS. 5 and 6). The package of Working Example 1 was obtained by means of the foregoing.

### Comparative Example 1

Except for the fact that curing of the semiconductor backside protective film was not carried out prior to sealing, a method identical to that of Working Example 1 was employed to obtain the package of Comparative Example 1.

Evaluation

If dislocation of the chip that was 5 mm square occurred this was evaluated as BAD, but if dislocation thereof did not occur this was evaluated as GOOD. Results are shown in TABLE 1.

TABLE 1

| | Working Example 1 | Comparative Example 1 |
|---|---|---|
| Positional dislocation | GOOD | BAD |

### LIST OF REFERENCE CHARACTERS

1 Laminated body

11 Semiconductor backside protective film

12 Adhesive sheet

121 First adhesive layer

122 Second adhesive layer

123 Base layer

21 Support body

31 Semiconductor chip

3 Assembly

4 Sealing sheet

41 Resin layer

42 Release liner

5 Composite body

71 Layer containing wiring

72 Bump

6 Pre-dicing semiconductor package

7 Semiconductor package

111 Post-dicing semiconductor backside protective film

711 Post-dicing layer

411 Resin portion

1. A semiconductor package manufacturing method comprising:
an operation in which a semiconductor chip is arranged over a semiconductor backside protective film that is arranged over an adhesive sheet;
an operation in which, following the operation in which the semiconductor chip is arranged over the semiconductor backside protective film, the semiconductor backside protective film is cured; and
an operation in which, following the operation in which the semiconductor backside protective film is cured, the semiconductor chip is sealed with resin.

2. The semiconductor package manufacturing method according to claim 1, wherein the adhesive sheet comprises a first adhesive layer, a second adhesive layer, and a base layer which is disposed between the first adhesive layer and the second adhesive layer;
the first adhesive layer has a property such that application of heat thereto causes reduction in peel strength thereof; and
the semiconductor package manufacturing method further comprises an operation in which a hard support body is secured to the second adhesive layer.

3. The semiconductor package manufacturing method according to claim 2, wherein the first adhesive layer comprises thermally expansible microspheres that expand as a result of application of heat thereto.

4. The semiconductor package manufacturing method according to claim 3, wherein a temperature for initiating thermal expansion of the thermally expansible microspheres is not less than 130° C.
